(19) United States
(12) Patent Application Publication
(10) Pub. No.: US 2017/0365570 A1
(43) Pub. Date: Dec. 21, 2017

(54) DEVICE COMPRISING A SUBSTRATE THAT INCLUDES AN IRRADIATED PORTION ON A SURFACE OF THE SUBSTRATE

(71) Applicant: QUALCOMM Incorporated, San Diego, CA (US)

(72) Inventors: Daeik Kim, Del Mar, CA (US); Chengjie Zuo, San Diego, CA (US); Mario Velez, San Diego, CA (US); Changhan Yun, San Diego, CA (US); Jonghae Kim, San Diego, CA (US)

(21) Appl. No.: 15/184,841

(22) Filed: Jun. 16, 2016

(51) Int. Cl. H01L 23/00; H01L 21/78; H01L 21/48; H01L 21/683

(52) U.S. Cl. CPC H01L 24/13; H01L 21/6836; H01L 21/78; H01L 24/97; H01L 21/4846; H01L 2224/13024; H01L 2221/68327; H01L 2924/19011; H01L 2924/19041; H01L 2924/19042; H01L 2924/19102; H01L 2224/12105

(57) ABSTRACT

Some implementations provide a device that includes a passive component and a substrate coupled to the passive component, where a surface of the substrate comprises a first irradiated portion. In some implementations, the first irradiated portion is located in an offset portion of the substrate. Some implementations provide an integrated device that includes a device layer and a substrate coupled to the device layer, where a surface of the substrate comprises a first irradiated portion. In some implementations, the first irradiated portion is located in an offset portion of the substrate.

### BACKGROUND

### Field

Various features relate to integrated devices, and more specifically to a device that includes a substrate comprising an irradiated portion on a surface of the substrate.

### Background

FIG. 1 illustrates a plan view of a wafer 100 that includes several uncut dies 102. Each uncut die includes a substrate, metal layers and dielectric layers. The wafer 100 is then cut into individual/single dies. FIG. 1 also illustrates vertical and horizontal scribe lines 102-104, Scribe lines are portions of the wafer 100 that are cut in order to singulate the dies (e.g., die 102).

Although FIG. 1 illustrates the scribe lines as being straight, during a fabrication process, the scribe lines are actually wavy. Thus, the scribe lines shown in FIG. 1 are actually not perfectly straight. Typically, the waviness of the scribe lines is greater 20 microns (gin). To account for the waviness of the scribe lines, offsets must be included in the wafer so that the scribe lines don't cut into the active portions of the dies 102. This additional offset, increases the overall size of the dies 102.

FIG. 2 illustrates a profile view of a device 200 that includes a substrate 201 and a passive component 202. The passive component 202 may be an integrated passive device (IPD). The passive component 202 is coupled to the substrate 201. One or more solder interconnect 214 (e.g., solder ball) may be coupled to the passive component 202. The device 200 includes an active portion 240 and offset portion 250. The active portion 240 includes the passive component 202 and portions of the substrate 201 that substantially overlaps (e.g., vertically overlaps) with the passive component 202. The offset portion 250 includes portions of the substrate 201 that does not overlap (e.g., vertically overlap) with the passive component 202. The offset portion 250 of the substrate 201 includes a portion that a scribe line is formed to singulate the device 200 from a wafer during a fabrication process. The offset portion 250 has to be large enough to account for the waviness of the edges caused by cracks (e.g., crack propagation) during the fabrication process. The waviness of such edges by a fabrication process may be about 25 microns (μm). Thus, the offset portion 250 has a width and/or length of about 25 microns (μm) or greater to ensure that crack propagation during the singulation process does not damage the passive component 202.

FIG. 3 illustrates a plan view of a plurality of devices 200 after a singulation process. As shown in FIG. 3, after the singulation process, the device 200 includes a passive component 202 coupled to a substrate 201, where the substrate 201 has edges or side walls with waviness of about 25 microns (μm) or greater. To protect from such crack propagation, the device 200 include an offset portion 250, which increases the overall size of the device 200.

Therefore, there is a need for a device with a more compact form factor, while at the same time protecting the device from cracks and meeting the needs of mobile devices, Internet of Things (IoT) devices, computing devices and/or wearable computing devices.

### SUMMARY

Various features relate to integrated devices, and more specifically to a device that includes a substrate that includes an irradiated portion on a surface of the substrate.

An example provides a device that includes a passive component and a substrate coupled to the passive component, where a surface of the substrate comprises a first irradiated portion.

Another example provides an integrated device that includes a device layer and a substrate coupled to the device layer, where a surface of the substrate comprises a first irradiated portion.

Another example provides a method for fabricating a device. The method provides a passive component. The method couples a substrate to the passive component. The method a first irradiated portion on a surface of the substrate.

Another example provides a method for fabricating an integrated device. The method provides a substrate. The method forms a device layer over the substrate. The method forms a first irradiated portion on a surface of the substrate.

### DRAWINGS

Various features, nature and advantages may become apparent from the detailed description set forth below when taken in conjunction with the drawings in which like reference characters identify correspondingly throughout.

FIG. 1 illustrates a wafer that includes uncut portions.

FIG. 2 illustrates a profile view of a device that includes a passive component.

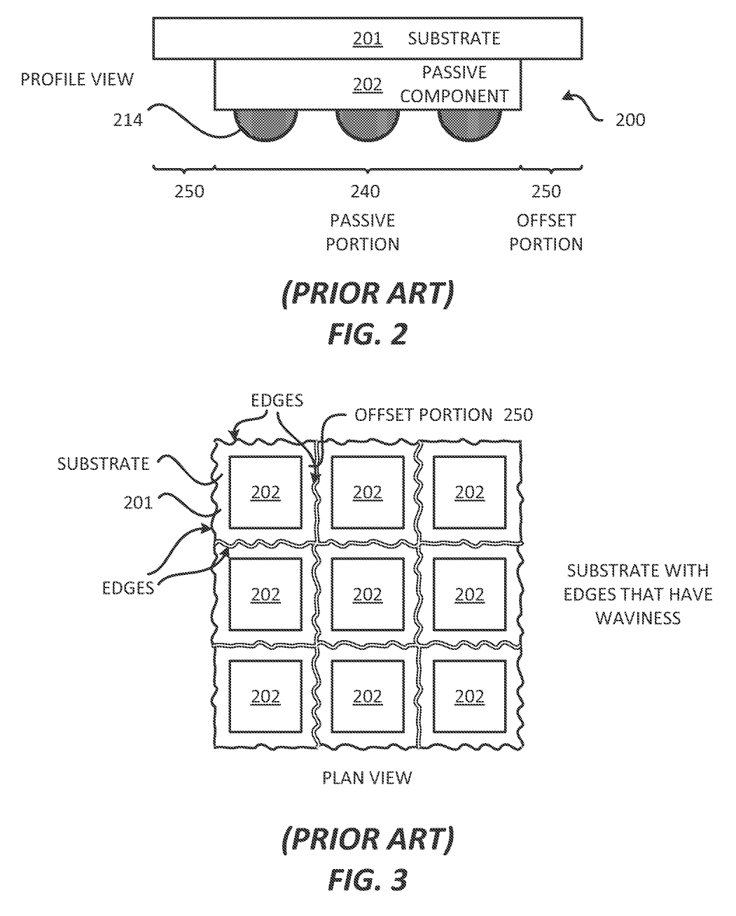

FIG. 3 illustrates a plan view of several devices that includes a passive component.

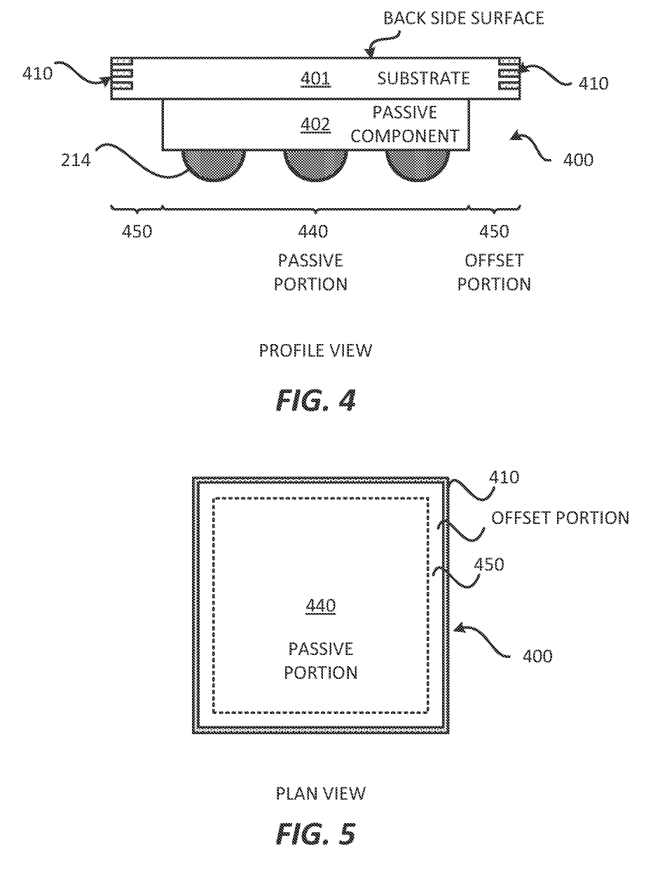

FIG. 4 illustrates a profile view of a passive component coupled to a substrate with reduced offset.

FIG. 5 illustrates a plan view of a passive component coupled to a substrate with reduced offset.

FIG. 6 illustrates a plan view of several devices that includes a passive component and a substrate with reduced offset.

FIG. 7 (which includes FIGS. 7A-7B) illustrates an example of a sequence for fabricating a passive component coupled to a substrate with reduced offset.

FIG. 8 illustrates an example of a flowchart of a method for fabricating a passive component coupled to a substrate with reduced offset.

FIG. 9 illustrates a profile view of another device that includes a passive component and a substrate with reduced offset.

FIG. 10 illustrates a profile view of a device that includes a passive component and a substrate with reduced offset, where portions of the substrate is removed.

FIG. 11 illustrates a profile view of a device that includes a passive component and a substrate with reduced offset, where portions of the substrate is removed.

FIG. 12 illustrates a profile view of a die with reduced offset.

FIG. 13 illustrates a plan view of a die with reduced offset.

FIG. 14 (which includes FIGS. 14A-14E) illustrates an example of a sequence for fabricating a die with reduced offset.

FIG. 15 illustrates an example of a flow chart of a method for fabricating a die with reduced offset.

FIG. 16 illustrates various electronic devices that may include the various integrated devices, integrated device packages, semiconductor devices, dies, integrated circuits, and/or packages described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Exemplary Device Comprising Substrate with Irradiated Portion

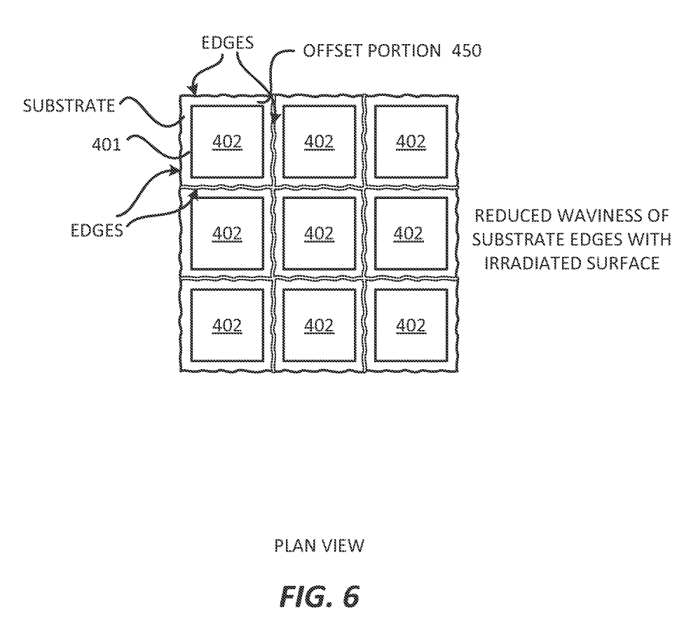

FIG. 4 illustrates a profile view of a device 400 that includes a substrate 401 and a passive component 402. The passive component 402 may be an integrated passive device (IPD). The passive component 402 may include a capacitor or an inductor. The passive component 402 is coupled to the substrate 401 (e.g., through an adhesive layer). One or more solder interconnect 414 (e.g., solder ball) may be coupled to the passive component 402. In some implementations, the passive component 402 may be considered the front side (e.g., active side) of the device 400, and the substrate 401 may be considered the back side of the device 400.

The device 400 includes an active portion 440 and offset portion 450. The active portion 440 includes the passive component 402 and portions of the substrate 401 that substantially overlaps (e.g., vertically overlaps) with the passive component 402. The offset portion 450 includes portions of the substrate 401 that does not overlap (e.g., vertically overlap) with the passive component 402. In some implementations, the offset portion 450 of the substrate 401 is free of active circuits and/or interconnects that may be configured as an electrical path for a signal to and/or from the passive component 402. In some implementations, the offset portion 450 of the substrate 401 includes a portion that a scribe line is formed to singulate the device 400 from a wafer during a fabrication process. In some implementations, the offset portion 450 has a width and/or length of about 20 microns (μm) or less. In some implementations, the offset portion 450 has a width and/or length of about 10 microns (μm) or less. In some implementations, an edge to edge distance between an edge of the substrate 401 and an edge of the passive component 402 is about 20 microns (μm) or less. In some implementations, an edge to edge distance between an edge of the substrate 401 and an edge of the passive component 402 is about 10 microns (μm) or less. In some implementations, the edge to edge distance may be represented by the offset portion 250.

As shown in FIG. 4, the substrate 401 includes at least one irradiated portion 410 (e.g., first irradiated portion, second irradiated portion, third irradiated portion). The irradiated portion 410 is formed in at least the offset portion 450 of the substrate 401. In some implementations, the irradiated portion 410 is formed close but not touching the active portion 440 of the substrate 401. The irradiated portion 410 is formed along at least one outer edge or perimeter of the substrate 401. In sonic implementations, several irradiated portions 410 are arranged in a column formation along at least one outer edge or perimeter of the substrate 401. FIG. 4 illustrates that the irradiated portion 410 is formed at least on a surface (e.g., back side surface) of the substrate 401. In some implementations, the back side surface of the substrate 401 is a surface of the substrate 401 that faces away from the passive component 402. In some implementations, a front side surface of the substrate 401 is coupled to the passive component 402, In some implementations, the front side surface of the substrate 401 is opposite to the back side surface of the substrate 401. In some implementations, the uses of the irradiated portion 410 enable better control of crack propagation during a singulation process of the dies and/or devices. In particular, the uses of the irradiated portion 410 on the surface of the substrate 401 may provide increased control of crack propagation of the substrate 401.

In some implementations, a laser is used to form the irradiated portion 410 of the substrate 401, In some implementations, several passes of the laser may be used to form several irradiated portions 410 of the substrate 401. The irradiated portion 410 of the substrate 401 includes a different property than the substrate 401. The irradiated portion 410 is not a cavity in the substrate 401. Rather, the irradiated portion 410 may have a different molecular property than other portions of the substrate 401. The irradiated portion 410 may be structurally weaker than other non-irradiated portions of the substrate 401, which makes the irradiated portion 410 more likely to break or crack than other portions of the substrate 401, resulting in better crack propagation control during singulation of the devices and/or dies, and reduces the waviness of the edges and/or side walls of the substrate 401. In some implementations, the waviness of the edges of substrate with an irradiated portion 410 is about 20 microns (μm) or less.

As will be further described below, in some implementations, the irradiated portion 410 may be formed in the substrate 401, and a portion of the substrate 401 is removed (e.g., grinded away) to expose the irradiated portion 410 on the back side surface of the substrate 401. In some implementations, exposing the irradiated portion 410 increases control of crack propagation and thus further reduces the waviness of the edges and/or side walls of the substrate 401. In some implementations, the waviness of the edges of the substrate with an irradiated portion 410 that is exposed (e.g., on a back side surface of the substrate) is about 10 microns (μm) or less.

As mentioned above, the use of irradiated portions results in less waviness of the scribe lines, edges and/or side walls during singulation. In some implementations, the waviness of a scribe line, edges and/or side walls is defined as a nonlinear cut, of the dicing plane that is perpendicular to the plane of the substrate and/or die's back side.

With the reduced waviness of the scribe lines, edges and/or sidewalls, the device 400 may be formed and fabricated with the offset portion 450 of the substrate 401 that is smaller, resulting in a device 400 that is smaller in size and/or dimension.

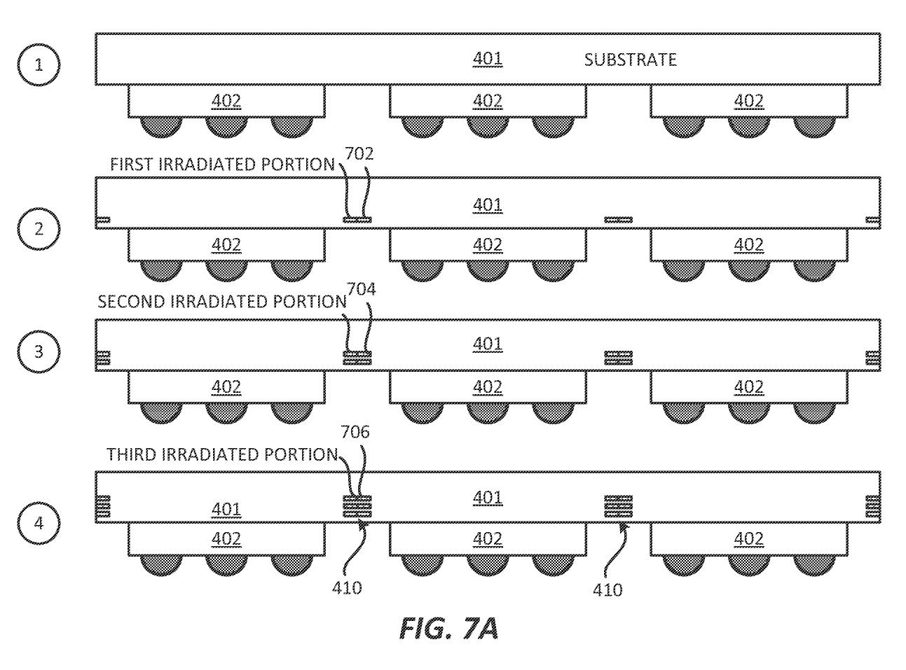

FIG. 5 illustrates a plan view (e.g., top view) of the device 400 that includes the active portion 440, the offset portion 450, and the irradiated portion 410. The active portion 440 includes the passive component 402 and a portion of the substrate 401. The offset portion 450 includes portions of the substrate 401 that does not overlap (e.g., vertically overlap) with the passive component 402. As further shown in FIG. 5, the offset portion 450 also includes the irradiated portion 410. The irradiated portion 410 is formed on and in the substrate 401, such that the irradiated portion 410 is formed along at least one outer edge or perimeter of the substrate 401.

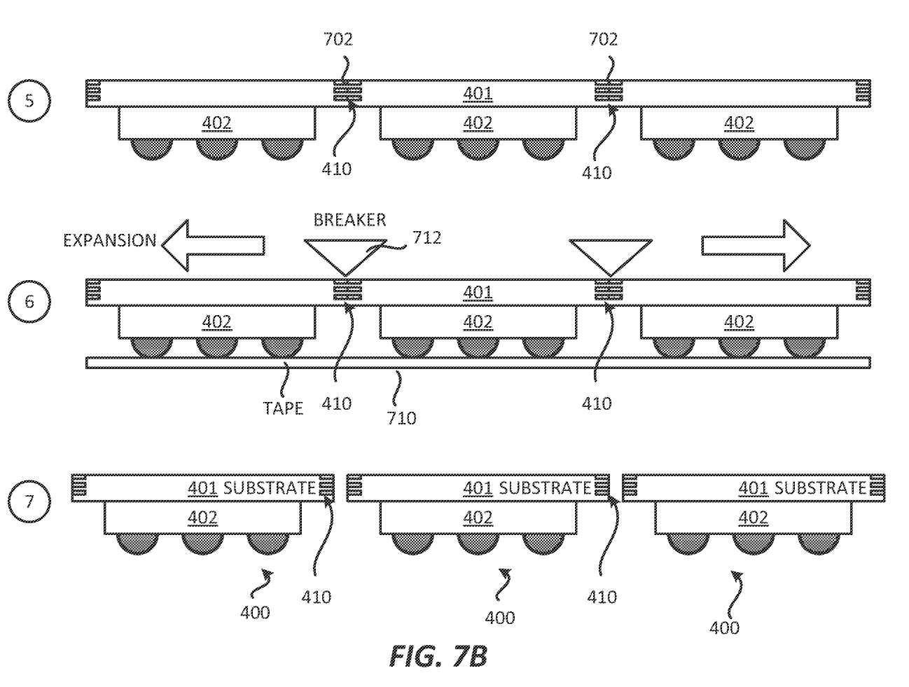

FIG. 6 illustrates a plan view of a plurality of devices 400 after a singulation process. As shown in FIG. 4, after the singulation process, the device 400 includes a passive component 402 coupled to a substrate 401, where the substrate 401 has edges or side walls with waviness of about 20 microns (μm) or less. In some implementations, the edges or side walls have a waviness of about 10 microns (μm) or less. To protect from such crack propagation, the device 400 include an offset portion 450, which decreases the overall size of the device 400.

Exemplary Sequence for Fabricating a Device Comprising a Substrate with an Irradiated Portion

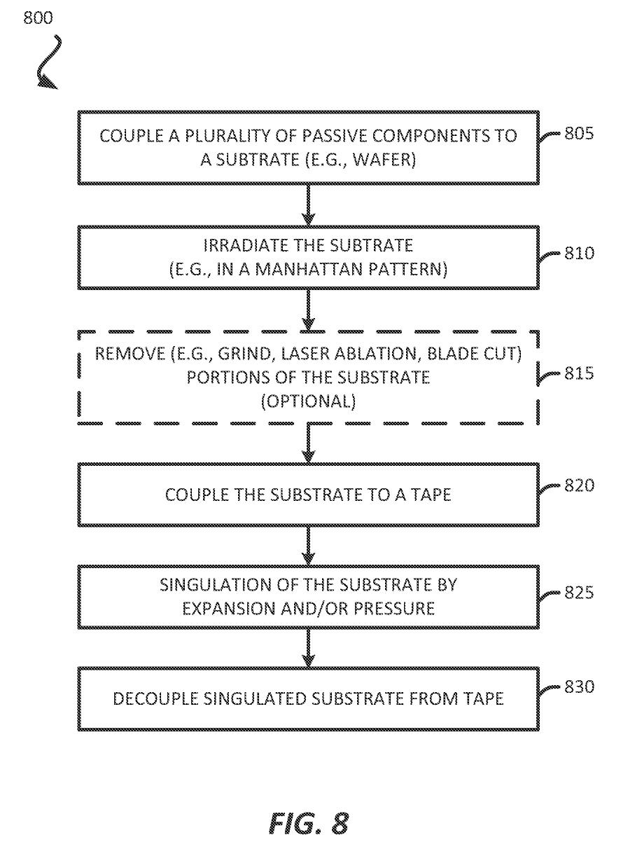

In some implementations, cutting (e.g., singulating) a wafer or substrate into individual devices (e.g., single die, single integrated device, single package) includes several processes. FIG. 7 (which includes FIGS. 7A-7B) illustrates an exemplary sequence for cutting a wafer into individual devices (e.g., singular devices). In some implementations, the sequence of FIGS. 7A-7B may be used to fabricate the device 400 of FIG. 4 or other devices described in the present disclose.

Stage 1 of FIG. 7A, illustrates a state after a plurality of passive components 402 are coupled to a substrate 401. The substrate 401 may be a wafer. The plurality of passive components 402 may be coupled to the substrate 401 through an adhesive layer (not shown).

Stage 2 illustrates a state after a laser is used for form several first irradiated portions 702 in the substrate 401. In some implementations, the first irradiated portions 702 are formed along imaginary lines (e.g., scribe line) between the passive components 402. In some implementations, the first irradiated portions 702 are formed in a Manhattan pattern in the substrate 401. It is noted that the first irradiated portions 702 are not a cavity in the substrate 401.

Stage 3 illustrates a state after a laser is used for form several second irradiated portions 704 in the substrate 401. In some implementations, the second irradiated portions 704 are formed along imaginary lines (e.g., scribe line) between the passive components 402. The second irradiated portions 704 are optional and may be formed above or below the first irradiated portions 702. In some implementations, the second irradiated portions 704 are formed in a Manhattan pattern in the substrate 401. It is noted that the second irradiated portions 704 are not a cavity in the substrate 401.

Stage 4 illustrates a state after a laser is used for form several third irradiated portions 706 in the substrate 401, in some implementations, the third irradiated portions 706 are formed along imaginary lines (e.g., scribe line) between the passive components 402. The third irradiated portions 706 are optional and may be formed above or below the first irradiated portions 702 and/or the second irradiated portions 704. In some implementations, the third irradiated portions 706 are formed in a Manhattan pattern in the substrate 401. It is noted that the second irradiated portions 704 are not a cavity in the substrate 401. In some implementations, one or more of the first irradiated portions 702, the second irradiated portion 704, and/or the third irradiated portion 706 may collectively represented as the irradiated portion 410. As mentioned above, the irradiated portion 410 is a structurally weaker portion of the substrate 401.

Stage 5 of FIG. 7B, illustrates a state after portions of the substrate 401 is removed. Different implementations may remove portions of the substrate 401 differently. For example, a hack side surface of the substrate 401 may be grinded away (e.g., mechanically grinded away, laser) to expose at least some of the irradiated portion 410 (e.g., first irradiated portion 702). In some implementations, exposing the irradiated portion provides increase crack propagation control during singulation, which reduces the waviness of the edges and/or side walls of the substrate 401. This approach may slightly increase the cost of fabricating a device because of the extra step of removing portions of the substrate 401. However, the added benefit of improved waviness and thus the ability to fabricate smaller devices may be worthwhile.

Stage 6 illustrates a state after the substrate 401 and the plurality of passive components 402 are coupled to a tape 710. The tape 710 is pulled to expand and/or stretch the substrate 401, which results in the substrate breaking along the irradiated portion 410. In some implementations, a breaker 712 is used to apply pressure along the irradiated portion 410, ensuring that the substrate 401 breaks along the irradiated portion 410 of the substrate 401.

Stage 7 illustrates a state after the devices 400 formed by the substrate 401 and the passive component 402 are decoupled from the tape 710. In some implementations, the substrate 401 has edges or side walls with waviness of about 20 microns (μm) or less. In some implementations, the edges or side walls have a waviness of about 10 microns (μm) or less. In some implementations, the offset portion of the substrate 401 has an edge to edge distance of about 20 microns (μm) or less. In some implementations, the offset portion of the substrate 401 has an edge to edge distance of about 10 microns (μm) or less.

Exemplary Flow chart of a Method for Fabricating a Device Comprising a Substrate with an Irradiated Portion

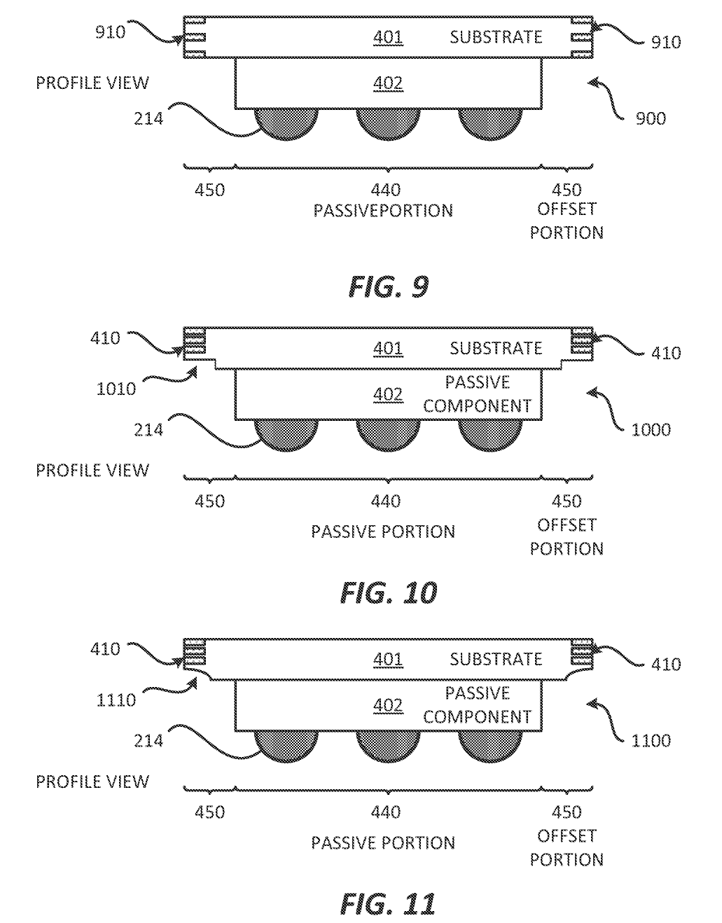

FIG. 8 illustrates an exemplary flow chart of a method for cutting a wafer or substrate into individual devices (e.g., singular devices). In some implementations, the method of FIG. 8 may be used to fabricate the device 400 of FIG. 4 or other devices described in the present disclose.

The method couples (at 805) a plurality of passive components 402 to a substrate 401. The substrate 401 may be a wafer. The plurality of passive components 402 may be coupled to the substrate 401 through an adhesive layer.

The method irradiated (at 810) a portion of the substrate (e.g., substrate 401). Different implementations may irradiate portions of the substrate differently. In some implementations, a laser is used to irradiate portions of the substrate in a Manhattan pattern along scribe lines and/or between passive components. In some implementations, one or more passes of a laser is used to form irradiated portions in the substrate. In some implementations, irradiated portions may be formed on a surface of the substrate. Stages 2-4 of FIG. 7A illustrates an example of irradiating a portion of a substrate.

The method optionally removes (at 815) portions of the substrate (e.g., substrate 401). In some implementations, removing portions of the substrate may include mechanically grinding away of the substrate to expose the irradiated portion of the substrate. As mentioned above, exposing the irradiated portion such that the irradiated portion is on the surface of the substrate has the unexpected effect of reducing the waviness of edges and/or sidewalls during singulation. In some implementations, a laser, a blade and/or a saw may be used to remove portions of the substrate to further the waviness of edges and/or sidewalls during singulation.

The method couples (at 820) the substrate (e.g., substrate 401) and the passive components (e.g., passive component 402) to a tape (e.g., tape 710). For example, solder interconnects of the passive components may be coupled to the tape.

The method singulates (at 825) the substrate and the passive components by stretching the tape and/or applying pressure on a region of the substrate comprising the irradiated portion (e.g., irradiated portion 410).

The method then decouples (at 830) the tape from the substrate and the passive components that have been singulated.

Exemplary Devices Comprising Substrate with Irradiated Portion

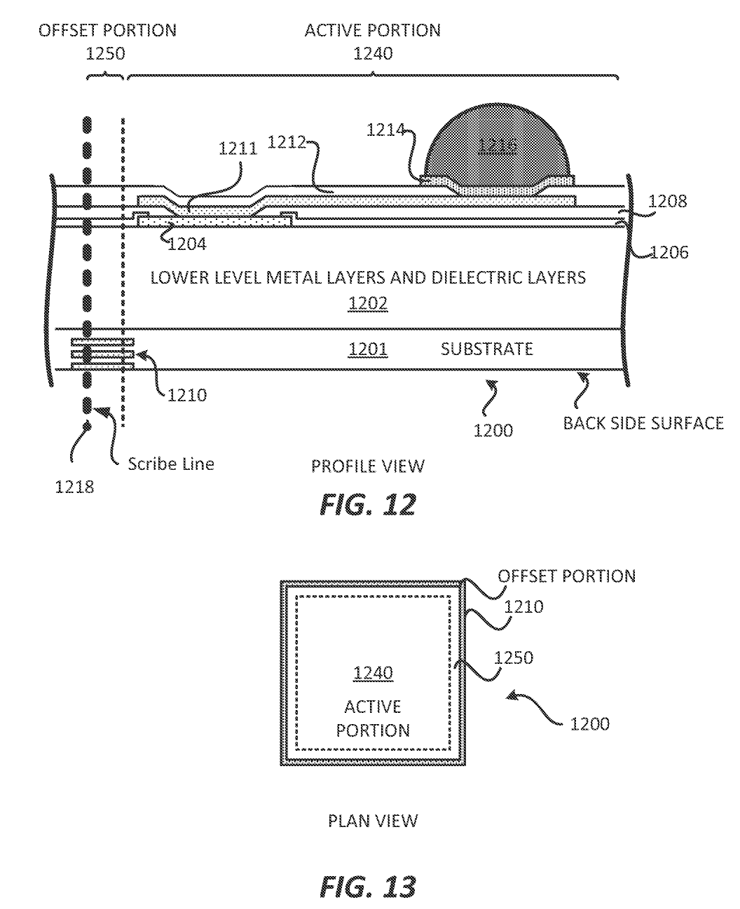

FIGS. 9-11 illustrate profile views of different devices (e.g., 900, 1000, 1100) that includes a substrate 401 and a passive component 402, where the substrate 401 includes an irradiated portion. The devices 900-1100 are similar to the device 400.

The device 900 of FIG. 9 is similar to the device 400, except that the substrate 401 of the device 900 includes an irradiated portion 910 (e.g., first irradiated portion, second irradiated portion, third irradiated portion) that is different than the irradiated portion 410. As shown in FIG. 9, the irradiated portion 910 is located on both surfaces (e.g., top surface, bottom surface) of the substrate 401. In some implementations, this design provides enhanced crack propagation control, which reduces waviness of the edges and/or sidewalls of the substrate 401.

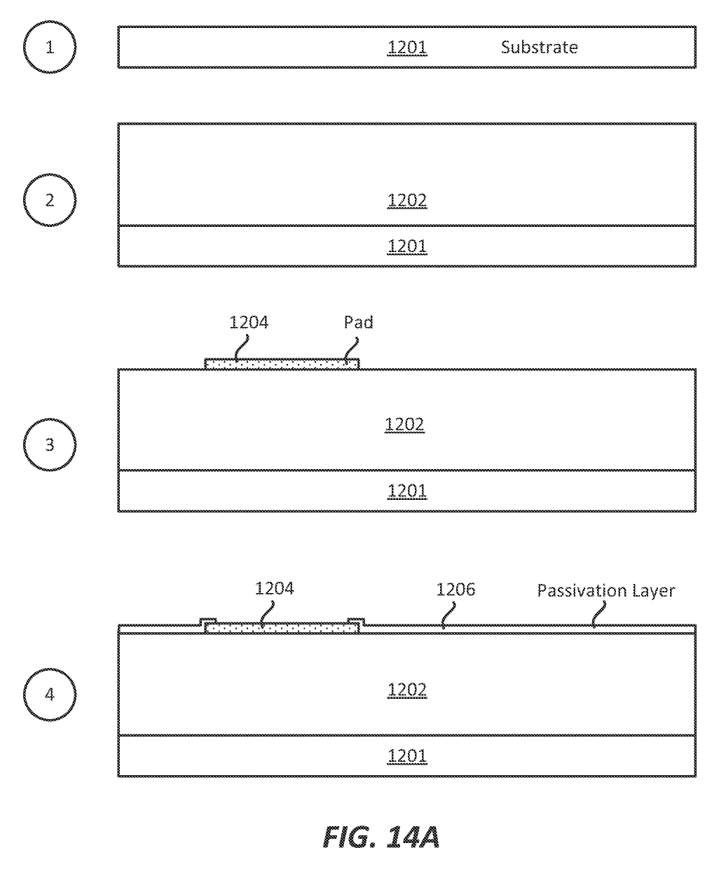

The device 1000 of FIG. 10 is similar to the device 400, except that the substrate 401 of the device 1000 includes a portion 1010 (e.g., bottom portion) that has been removed using a blade and/or a saw, in some implementations, this design provides enhanced crack propagation control, which reduces waviness of the edges and/or sidewalls of the substrate 401.

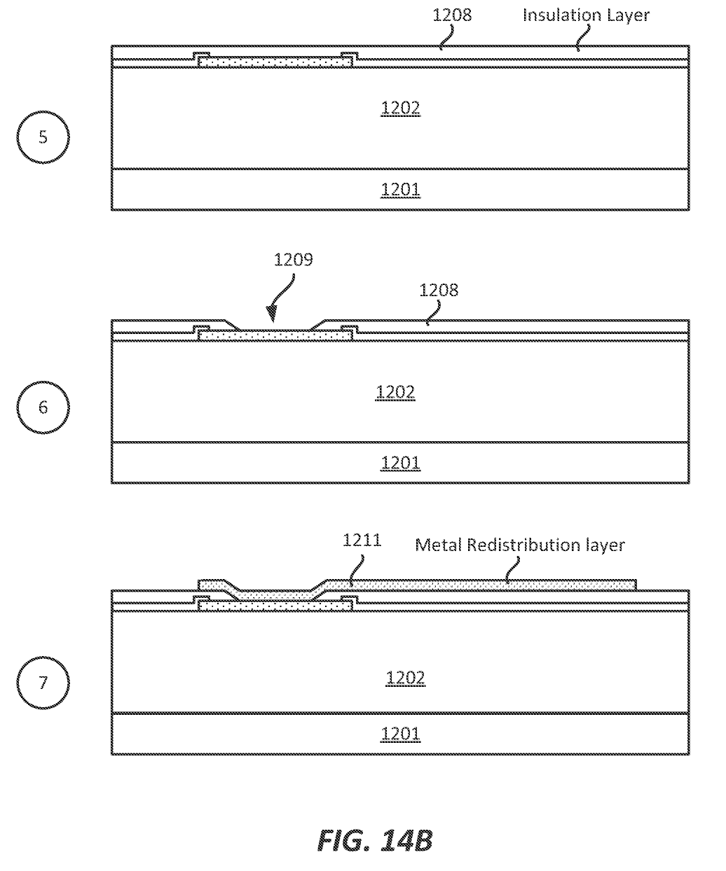

The device 1100 of FIG. 11 is similar to the device 400, except that the substrate 401 of the device 1000 includes a portion 1110 (e.g., bottom portion) that has been removed using a laser. In some implementations, this design provides enhanced crack propagation control, which reduces waviness of the edges and/or sidewalls of the substrate 401.

The present application describes a design for crack propagation control for substrate coupled to a passive component and/or a device. In some implementations, such a design can also be applicable to other devices, such as an integrated device and /or a package (e.g., wafer level package (WLP)).

Exemplary Device Comprising Substrate with Irradiated Portion

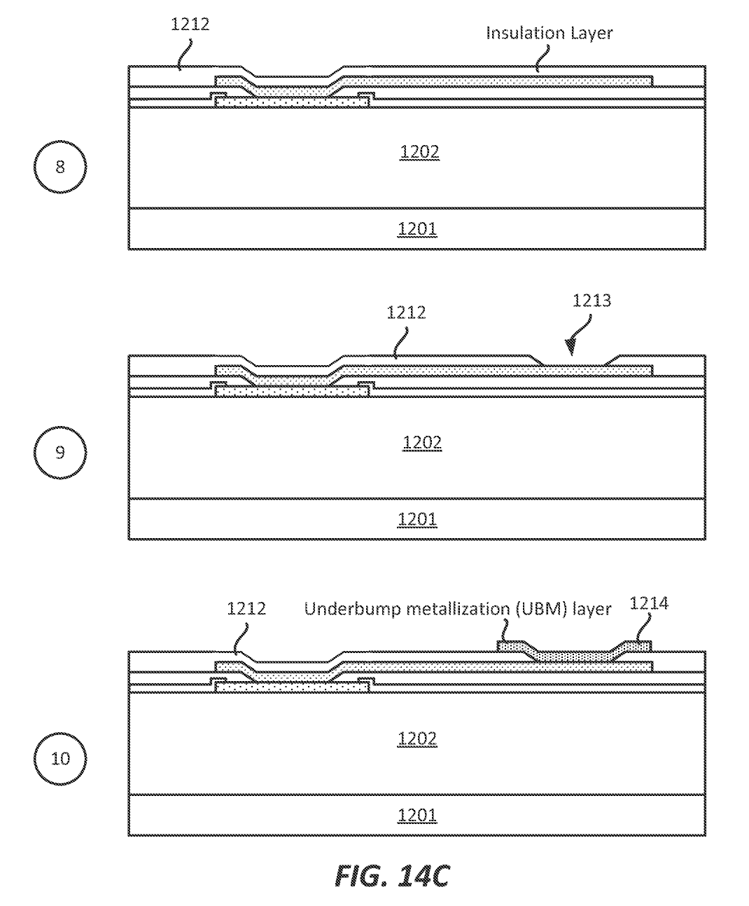

FIG. 12 illustrates a side view of a device 1200 that includes a substrate with an irradiated portion, in some implementations, the device 1200 includes a die, an integrated device, and/or a package (e.g., wafer level package (WLP)). The device 1200 includes a substrate 1201, several lower level metal layers and dielectric layers 1202, a pad 1204, a passivation layer 1206, a first insulation layer 1208, a first metal redistribution layer 1211, a second insulation layer 1212, and an under bump metallization (UBM) layer 1214. The device 1200 includes a device layer, which defines the circuits (e.g., transistors, switches) of the device 1200. The device layer may be formed on the substrate 1201 and/or the several lower level metal layers and dielectric layers 1202 of the device 1200.

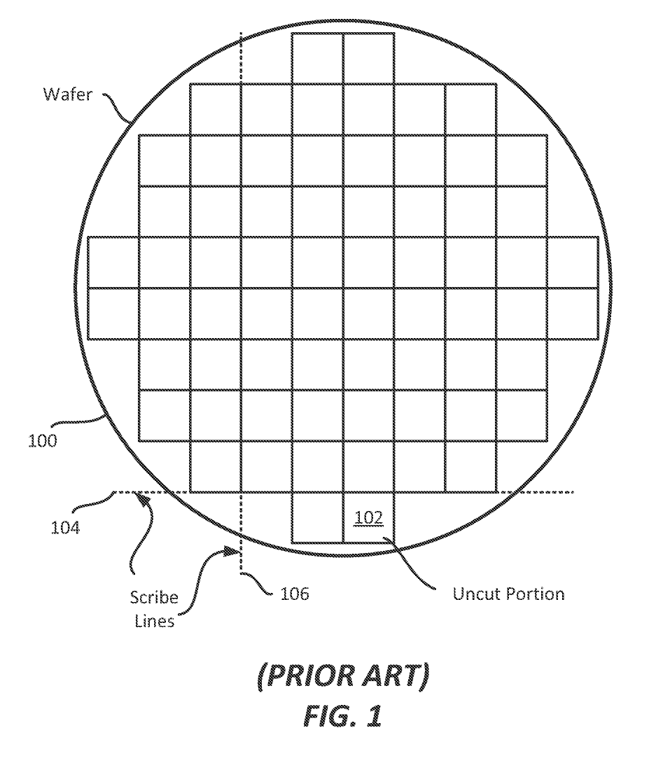

FIG. 12 also illustrates a solder ball 1216 on the device 1200. Specifically, the solder ball 1216 is coupled to the UBM layer 1214. The pad 1204, the first metal redistribution layer 1211 and the UBM layer 1214 are a conductive material (e.g., copper). The first insulation layer 1208 and the second insulation layer 1212 are polyimide layers (PI), Polybenzoxazole (PBO) or other polymer layers used for repassivation. FIG. 12 also illustrates a region of the device 1200 that is cut to create individual dies, integrated devices and/or packages. This region of the device 1200 is illustrated by the scribe line 1218, which may correspond to either of the scribe lines 104-106 of FIG. 1. FIG. 12 illustrates that the device 1200 includes an active portion 1240 and an offset portion 1250. The active portion 1240 of the device 1200 includes various active components. The offset portion 1250 is about 20 microns (μm) or less to account for the waviness of edges during a singulation process. In some implementations, the offset portion 1250 is about 10 microns (μm) or less.

FIG. 12 also illustrates that the substrate 1201 includes at least one irradiated portion 1210, which is further described below. The device 1200 also includes an active portion 1240 and offset portion 1250. The active portion 1240 includes a first portion of the substrate 1201, a first portion of the lower level metal layers and dielectric layers 1202, the pad 1204, the first metal redistribution layer 1211, and the UBM layer 1214. The active portion 1240 may also include the active device layer or device layer that forms the circuits (e.g., diodes and transistors) in the device 1200.

The offset portion 1250 includes a second portion of the substrate 1201, a second portion of the lower level metal layers and dielectric layers 1202, a portion of the passivation layer 120f, a portion of the first insulation layer 1208, and a portion of the second insulation layer 1212. In some implementations, the offset portion 1250 is flee of active circuits and/or interconnects that may be configured as an electrical path for a signal to and/or from the lower level metal layers and dielectric layers 1202.

In some implementations, the offset portion 1250 of the substrate 1201 includes a portion that a scribe line is formed to singulate the device 1200 from a wafer during a fabrication process. In some implementations, the offset portion 1250 has a width and/or length of about 20 microns (μm) or less. In some implementations, the offset portion 1250 has a width and/or length of about 10 microns (μm) or less. In some implementations, an edge to edge distance between an edge of the substrate 1201 and an edge of metal layers of the lower level metal layers and dielectric layers 1202 (e.g., device layer) is about 20 microns (μm) or less. In some implementations, an edge to edge distance between an edge of the substrate 1201 and an edge of metal layers of the lower level metal layers and dielectric layers 1202 (e.g., device layer) is about 10 microns (μm) or less. In some implementations, the edge to edge distance may be represented by the offset portion 1250.

As shown in FIG. 12, the substrate 1201 includes at least one irradiated portion 1210 (e.g., first irradiated portion, second irradiated portion, third irradiated portion). The irradiated portion 1210 is formed in at least the offset portion 1250 of the substrate 1201. In some implementations, the irradiated portion 1210 is formed in the active portion 1240 of the substrate 1201. The irradiated portion 1210 is formed along at least one outer edge or perimeter of the substrate 1201. In some implementations, several irradiated portions 1210 are arranged in a column formation along at least one outer edge or perimeter of the substrate 1201. FIG. 12 illustrates that the irradiated portion 1210 is formed at least on a surface (e.g., back side surface) of the substrate 1201. In some implementations, the back side surface of the substrate 1201 is a surface of the substrate 1201 that faces away from the lower level metal layers and dielectric layers 1202. In some implementations, a front side surface of the substrate 1201 is coupled to the lower level metal layers and dielectric layers 1202 (e.g., device layer). In some implementations, the front side surface of the substrate 1201 is opposite to the back side surface of the substrate 1201.

In some implementations, a laser is used to form the irradiated portion 1210 of the substrate 1201. In some implementations, several passes of the laser may be used to form several irradiated portions 1210 of the substrate 1201. The irradiated portion 1210 of the substrate 1201 includes a different property than the substrate 1201. The irradiated portion 1210 is not a cavity in the substrate 1201. Rather, the irradiated portion 1210 may have a different molecular properly than other portions of the substrate 1201. The irradiated portion 1210 may be structurally weaker than other non-irradiated portions of the substrate 1201, which makes the irradiated portion 1210 more likely to break or crack than other portions of the substrate 1201.

As will be further described below, in some implementations, the irradiated portion 1210 may be formed in the substrate 1201, and a portion of the substrate 1201 is removed (e.g., grinded away) to expose the irradiated portion 1210 on the back side surface of the substrate 1201.

In some implementations, the use of irradiated portions results in less waviness of the scribe lines during singulation. In some implementations, the waviness of scribe tines on substrate with the irradiated portion (e.g., irradiated portion 1210) may be about 20 microns (μm) or less. In some implementations, the waviness of scribe lines on substrate with the irradiated portion (e.g., irradiated portion 1210) may be about 10 microns (μm) or less. In some implementations, the waviness of scribe lines is further reduced when the irradiated portion is located on a surface (e.g., back side surface) of the substrate 1201.

With the reduced waviness of the scribe lines, the device 1200 may be formed and fabricated with the offset portion 1230 of the substrate 1201 that is smaller, resulting in a device 1200 (e.g., die, package) that is smaller in size and/or dimension.

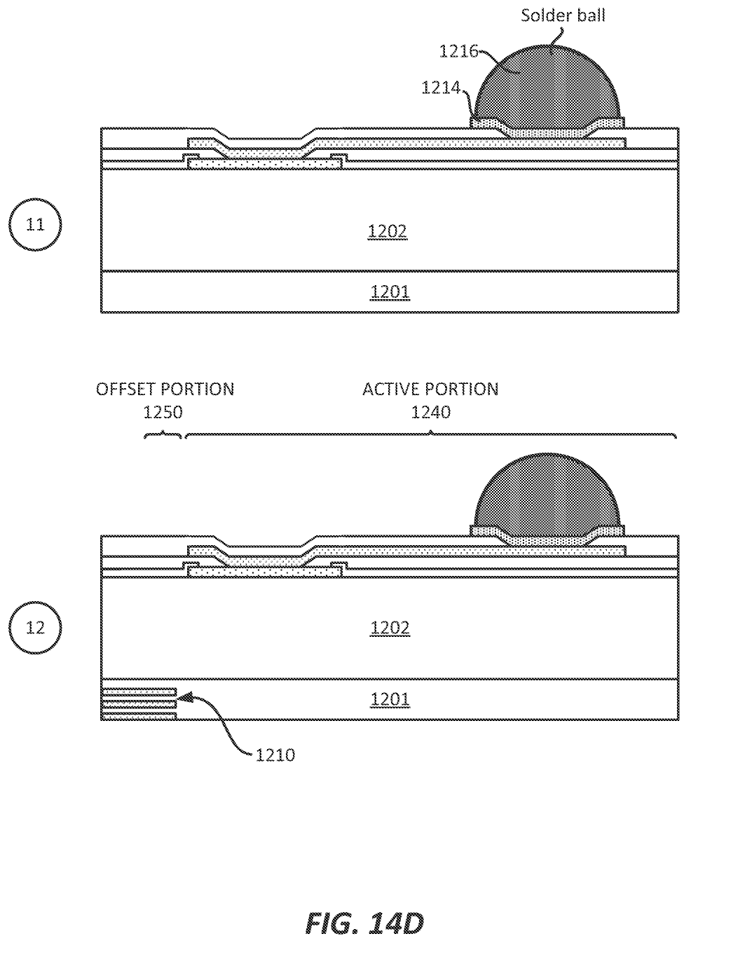

FIG. 13 illustrates a plan view (e.g., top view) of the device 1200 that includes the active portion 1240, the offset portion 1250, and the irradiated portion 1210. The active portion 1240 includes the lower level metal layers and dielectric layers 1202 and a portion of the substrate 1201. The offset portion 1250 includes portions of the substrate 1201 that does not include active components (e.g., circuit, diode, transistor). As further shown in FIG. 13, the offset portion 1230 also includes the irradiated portion 1210. The irradiated portion 1210 is formed on and in the substrate 1201, such that the irradiated portion 1210 is formed along at least one outer edge or perimeter of the substrate 1201.

Exemplary Sequence for Fabricating a Device Comprising a Substrate with an Irradiated Portion

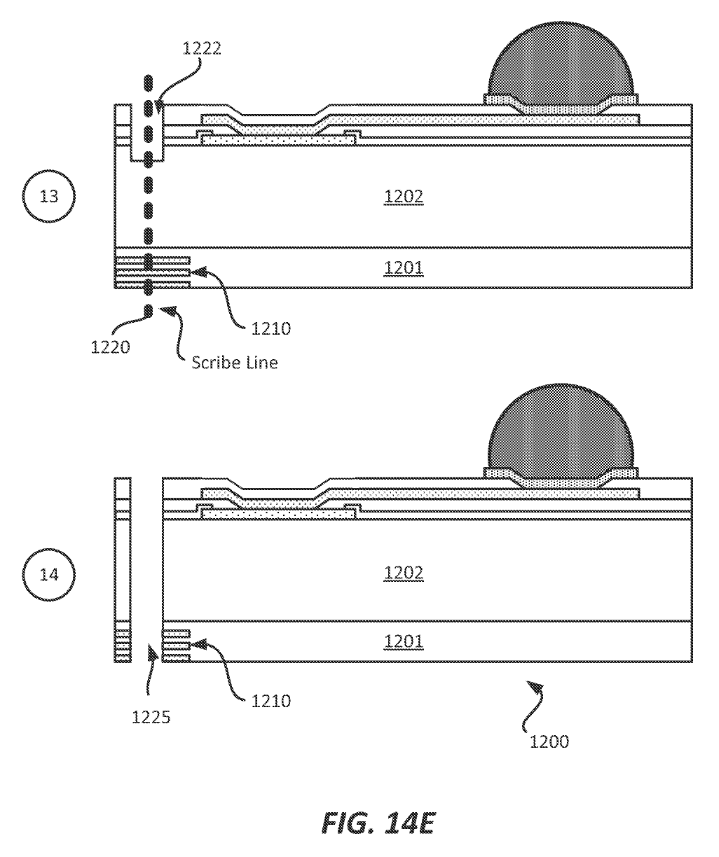

In some implementations, cutting (e.g., singulating) a wafer into individual dies (e.g., single die) includes several processes. FIG. 14 (which includes FIGS. 14A-14E) illustrates an exemplary sequence for cutting a wafer into individual dies (e.g., singular dies). In some implementations, the sequence of FIGS. 14A-14E may be used to fabricate the die of FIG. 12 or other dies described in the present disclose. It should also be noted that the sequence of FIGS. 14A-14E may be used to fabricate other devices.

As shown in stage 1 of FIG. 14A, a substrate (e.g., substrate 1201) is provided. In some implementations, the substrate is a wafer. Different implementations may use different materials for the substrate (e.g., silicon substrate, glass substrate).

At stage 2, several lower level metal and dielectric layers (e.g., lower level metal and dielectric layers 1202) are formed on the substrate. Different implementations may provide different number of lower level metal and dielectric layers (e.g., M1 metal layer, M2 metal layer, M3 metal layer, M4 metal layer, M5 metal layer, M6 metal layer, M7 metal layer). In some implementations, the lower level metal and dielectric layers are a device layer on an integrated device.

In some implementations, circuits, routes and/or interconnects are also provided. However, for the purpose of simplification and clarity, circuits, routes and/or interconnects are not shown.

At stage 3, at least one pad (e.g., pad 1204) is provided on the lower level metal and dielectric layers 1202. In some implementations, the pad is coupled to one of the lower level metal layer (e.g., the top lower level metal layer, M7 metal layer). In some implementations, the pad 1204 is an aluminum pad. However, different implementations may use different materials for the pad 1204. Different implementations may use different processes for providing the pad on the lower level metal and dielectric layers 1202. For example, in sonic implementations, a lithography and/or etching process may be use to provide the pad 1204 on the lower level metal and dielectric layers 1202.

At stage 4, a passivation layer (e.g., passivation layer 1206) is provided on the lower level metal layers and dielectric layers 1202. Different implementations may use different materials for the passivation layer. As shown in stage 4, the passivation layer 406 is provided on the lower level metal layers and dielectric layers 1202 such that at least a portion of the pad 1204 is exposed.

At stage 5 of FIG. 14B, a first insulation layer (e.g., first insulation layer 1208) is provided on the passivation layer 1206 and the pad 1204. Different implementations may use different materials for the first insulation layer 1208. For example, the first insulation layer 120$ may be a Polybenzoxazole (PhO) layer or a polymer layer.

At stage 6, a cavity (e.g., cavity 1209) is provided/created in the first insulation layer 1208. As farther shown in stage 6, the cavity 1209 is created over the pad 1204. Different implementations may create the cavity 1209 differently. For example, the cavity 1209 may be provided/created by etching the first insulation layer 1208.

At stage 7, a first metal redistribution layer is provided. Specifically, a first metal redistribution layer 1211 is provided over the pad 1204 and the first insulation layer 1208, As shown in stage 7, the first metal redistribution layer 1211 is coupled to the pad 1204. In some implementations, the first metal redistribution layer 1211 is a copper layer.

At stage 8 of FIG. 14C, a second insulation layer (e.g., second insulation layer 1212) is provided on the first insulation layer 1208 and the first metal redistribution layer 1211. Different implementations may use different materials for the second insulation layer 1212. For example, the second insulation layer 1212 may be a Polybenzoxazole (PbO) layer or a polymer layer.

At stage 9, a cavity (e.g., cavity 1213) is provided/created in the second insulation layer 1212. Different implementations may create the cavity 1213 differently. For example, the cavity 1213 may be provided/created by etching the second insulation layer 1212.

At stage 10, an under bump metallization (UBM) layer is provided. Specifically, an under bump metallization (UBM) layer 1214 is provided in the cavity 1213 of the second insulation layer 1212. As shown at stage 10, the UBM layer 1214 is coupled to the first metal redistribution layer 1211. In some implementations, the UBM layer 1214 is a copper layer.

At stage 11 of FIG. 14D, a solder ball is provided on the UBM layer. Specifically, a solder ball 1216 is coupled to the UBM layer 1214. In some implementations, the bump area includes the UBM layer 1214 and/or the solder ball 1216. In some implementations, the pad area includes the pad 1204.

At stage 12, a laser is used to irradiate a portion of the substrate 1201. In some implementations, several passes of the laser may be used to irradiate several portions of the substrate 1201. The irradiated portion 1210 (which may include a first irradiated portion, a second irradiated portion, a third irradiated portion) of the substrate includes a different property than the substrate 1201. The irradiated portion 1210 is not a cavity in the substrate 1201. Rather, the irradiated portion 1210 may have a different molecular property than the substrate 1201. The irradiated portion 1210 may be structurally weaker than other non-irradiated portions of the substrate 1201, which makes the irradiated portion 1210 more likely to break or crack than other portions of the substrate 1201. In some implementations, the irradiated portion 1210 may be located in an offset portion of the die and/or a scribe line portion of the wafer and/or substrate 1201. The irradiated portion 1210 may be formed on a back side surface of the substrate 1201. In some implementations, the irradiated portion 1210 may be formed in the substrate 1201 and a portion of the substrate 1201 is removed (e.g., grinded away) to expose the irradiated portion 1210 on the back side surface of the substrate 1201.

At stage 13 of FIG. 14E, a cavity is optionally formed in the wafer. Specifically, a cavity 1222 is created in the second insulation layer 1212, the first insulation layer 1208, the passivation layer 1206, and at least one of the lower level metal and dielectric layers 1202. Different implementations may have cavities and/or trenches with different shapes. As further shown in stage 12, the cavity 1222 is provided/created along a scribe line (e.g., scribe line 1220). As previously described above, a scribe line is a region of a wafer that will be cut in order to provide/manufacture one or more dies, Different implementations may use different processes for providing/creating the cavity/trench. For example, a laser may be use to create the cavity 1222. In such instances, several passes of a laser may be use to create the cavity 1222. It should also be noted that the cavity along the scribe line may traverse different parts of the wafer in different implementations. That is, in some implementations, the cavity (e.g., cavity 1222) along a scribe line may have different depths.

At stage 14, a portion of the wafer is singulated along the cavity 1222 (e.g., along the scribe line 1220). In some implementations, the wafer is singulated in a matter similar as described in FIG. 7A-7B, by using an expander (e.g., tape) and breaker.

Exemplary Flowchart of a Method for Fabricating a Device Comprising a Substrate with an Irradiated Portion

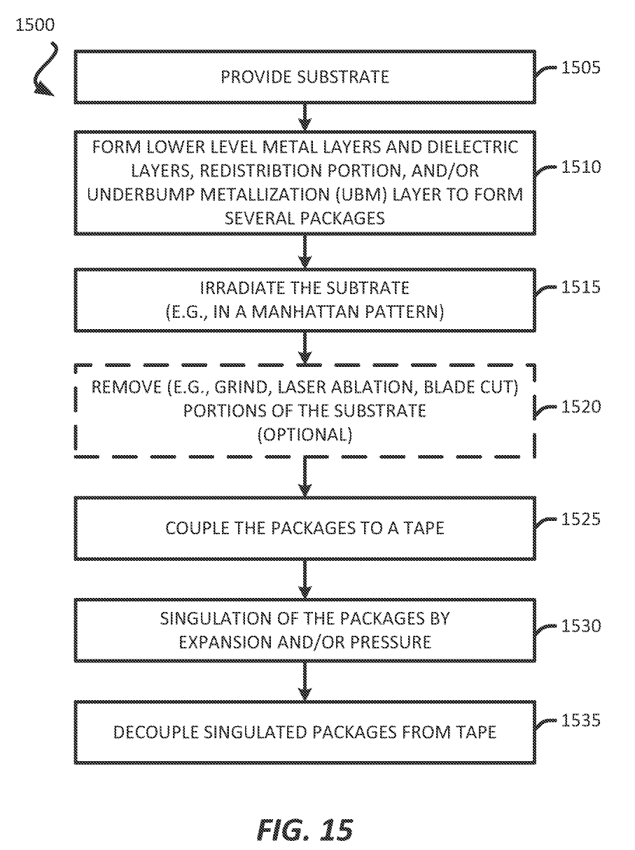

FIG. 15 illustrates an exemplary flow chart of a method for cutting a wafer into individual devices (e.g., singular devices). In some implementations, the method of FIG. 15 may be used to fabricate the device 1200 of FIG. 12 or other devices described in the present disclose.

The method provides (at 1505) a substrate (e.g., substrate 1201). In some implementations, providing (at 1505) the substrate includes providing a wafer (e.g., silicon wafer). However, different implementations may use different materials for the substrate (e.g., glass substrate).

The method then forms (at 1510) lower level metal layers and dielectric layers, a redistribution portion, at least one underbump metallization (UBM) layer, which may form several packages (e.g., several unsingulated packages). In some implementations, forming the lower level metal layers and the dielectric layers may include form the active device layers of a device. The active device layers may be formed on the substrate. Examples of forming lower level metal layers and dielectric layers, a redistribution portion, at least one underbump metallization (UBM) layer are described and illustrated in FIGS. 14A-14D.

The method irradiated (at 1515) a portion of the substrate (e.g., substrate 1201). Different implementations may irradiate portions of the substrate differently. In some implementations, a laser is used to irradiate portions of the substrate in a Manhattan pattern along scribe lines and/or between passive components. In some implementations, one or more passes of a laser is used to form irradiated portions in the substrate, in some implementations, irradiated portions may be formed on a surface of the substrate. Stage 2-4 of FIG. 7A and Stage 12 of FIG. 14D illustrate examples of irradiating a portion of a substrate.

The method optionally removes (at 1520) portions of the substrate (e.g., substrate 1201). In some implementations, removing portions of the substrate may include mechanically grinding away of the substrate to expose the irradiated portion of the substrate. As mentioned above, exposing the irradiated portion such that the irradiated portion is on the surface of the substrate has the unexpected effect of reducing the waviness of edges and/or sidewalls during singulation. In some implementations, a laser, a blade and/or a saw may be used to remove portions of the substrate to further the waviness of edges and/or sidewalls during singulation.

The method couples (at 1525) the unsingulated packages (e.g., wafer) to a tape (e.g., tape 710). For example, solder interconnects of the unsingulated packages may be coupled to the tape.

The method singulates (at 1530) the unsingulated packages by stretching the tape and/or applying pressure on a region of the substrate comprising the irradiated portion (e.g., irradiated portion 1210).

The method then decouples (at 1535) the tape from the singulated packages.

### Exemplary Electronic Devices

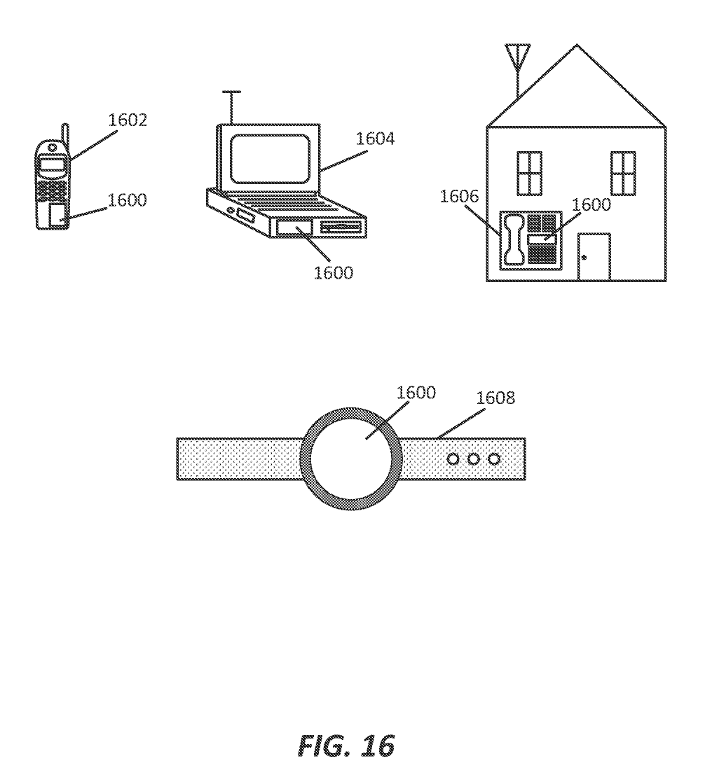

FIG. 16 illustrates various electronic devices that may be integrated with any of the aforementioned integrated device, semiconductor device, integrated circuit, die, interposer, package or package-on-package (PoP). For example, a mobile phone device 1602, a laptop computer device 1604, a fixed location terminal device 1606, a wearable device 1608 may include an integrated device 1600 as described herein. The integrated device 1600 may be, for example, any of the integrated circuits, dies, integrated devices, integrated device packages, integrated circuit devices, device packages, integrated circuit (IC) packages, package-on-package devices described herein. The devices 1602, 1604, 1606, 1608 illustrated in FIG. 16 are merely exemplary. Other electronic devices may also feature the integrated device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watch, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 4. 5, 6, 7A-7B, 8, 9, 10, 11, 12, 13, 14A-14E and/or 15 may be rearranged and/or combined into a single component, process, feature or function or embodied in several components, processes, or functions. Additional elements, components, processes, and/or functions may also be added without departing from the disclosure. It should also be noted that FIGS. 4, 5, 6, 7A-7B, 8, 9, 10, 11, 12, 13, 14A-14E and/or 15 and its corresponding description in the present disclosure is not limited to dies and/or ICs. In some implementations, F FIGS. 4, 5, 6, 7A-7B, 8, 9, 10, 11, 12, 13, 14A-14E and/or 15 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another even if they do not directly physically touch each other.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

One or more devices (e.g., die) in an integrated device package may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium and/or a processor-readable medium. The computer-readable medium and/or a processor-readable medium may be a non-transitory computer-readable medium and/or a non-transitory processor-readable medium. A non-transitory computer-readable medium and/or a non-transitory processor-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may reside in a memory of an integrated device package, external to the integrated device package, or distributed across multiple entities including the integrated device package. The computer-readable medium and/or the processor-readable medium may be embodied in a computer program product. By way of example, a computer program product may include a computer-readable medium in packaging materials, Those skilled in the art will recognize how best to implement the described functionality presented throughout this disclosure depending on the particular application and the overall design constraints imposed on the overall system.

The algorithms described herein may also be efficiently implemented in software and/or embedded in hardware, it is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein. Additional elements, components, steps, and/or functions may also be added or not utilized without departing from the disclosure.

Also, it is noted that at least some implementations have been described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, in some aspects, a process may correspond to a method, a function, a procedure, a subroutine, a subprogram, etc. When a process corresponds to a function, its termination corresponds to a return of the function to the calling function or the main function. One or more of the various methods described herein may be partially or fully implemented by programming (e.g., instructions and/or data) that may be stored in a machine-readable, computer-readable, and/or processor-readable storage medium, and executed by one or more processors, machines and/or devices. A processor may include one or more processors. A processor may include one or more processor core.

Those of skill in the art would further appreciate that the various illustrative logical blocks, modules, circuits, and algorithm steps described in connection with the implementations disclosed herein may be implemented as hardware, software, firmware, middleware, microcode, or any combination thereof. To clearly illustrate this interchangeability, various illustrative components, blocks, modules, circuits, and steps have been described above generally in terms of their functionality. Whether such functionality is implemented as hardware or software depends upon the particular application and design constraints imposed on the overall system.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a passive component; and
a substrate coupled to the passive component, wherein a surface of the substrate comprises a first irradiated portion.

2. The device of claim 1, wherein the first irradiated portion is along at least one edge of the substrate.

3. The device of claim 1, wherein the substrate further comprises a second irradiated portion in the substrate.

4. The device of claim 1, wherein an edge to edge distance between the passive component and the substrate is about 20 microns or less.

5. The device of claim 1, wherein an edge to edge distance, between the passive component and the substrate is about 10 microns or less.

6. The device of claim 1, wherein the passive component comprises an integrated passive device (IPD).

7. The device of claim 6, wherein the integrated passive device (IPD) comprises a capacitor or an inductor.

8. The device of claim 1, wherein the device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in a automotive vehicle.

9. An integrated device comprising:
a device layer; and
a substrate coupled to the device layer, wherein a surface of the substrate comprises a first irradiated portion.

10. The integrated device of claim 9, wherein the first irradiated portion is along at least one edge of the substrate.

11. The integrated device of claim 9, wherein substrate further comprises a second irradiated portion in the substrate,

12. The integrated device of claim 9, wherein an edge to edge distance between the device layer and the substrate is about 20 microns or less.

13. The integrated device of claim 9, wherein an edge to edge distance between the device layer and the substrate is about 10 microns or less.

14. The integrated device of claim 9, wherein the integrated device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in a automotive vehicle.

15. A method for fabricating a device, comprising:
providing a passive component;
coupling a substrate to the passive component; and
forming a first irradiated portion on a surface of the substrate.

16. The method of claim 15, wherein the first irradiated portion is along at least one edge of the substrate.

17. The method of claim 15, wherein forming the first irradiated portion on a surface of the substrate comprises:
forming the first irradiated portion in the substrate; and
removing a portion of the substrate to expose the first irradiated portion on the surface of the substrate.

18. The method of claim 15, wherein an edge to edge distance between the passive component and the substrate is about 20 microns or less.

19. The method of claim 15, wherein an edge to edge distance between the passive component and the substrate is about 10 microns or less.

20. A method for fabricating an integrated device, comprising:
providing a substrate;
forming a device layer over the substrate; and
forming a first irradiated portion on a surface of the substrate.

21. The method of claim 20, wherein the first irradiated portion is formed along at least one edge of the substrate.

22. The method of claim 20, wherein forming the first irradiated portion on a surface of the substrate comprises:
forming the first irradiated portion in the substrate; and
removing a portion of the substrate to expose the first irradiated portion on the surface of the substrate.

23. The method of claim 20, wherein an edge to edge distance between the device layer and the substrate is about 20 microns or less.

24. The method of claim 20, wherein an edge to edge distance between the device layer and the substrate is about 10 microns or less.
